(19) United States
(12) Patent Application Publication
(10) Pub. No.: US 2025/0014912 A1
(43) Pub. Date: Jan. 9, 2025

(54) METHOD FOR PROTECTING ACTIVE LAYERS OF ELECTRONIC CHIPS

(71) Applicant: COMMISSARIAT A L'ENERGIE ATOMIQUE ET AUX ENERGIES ALTERNATIVES, Paris (FR)

(72) Inventor: Emilie BOURJOT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/765,760

(22) Filed: Jul. 8, 2024

(30) Foreign Application Priority Data
Jul. 9, 2023 (FR) 2307330

(51) Int. Cl. H01L 21/56; H01L 21/02; H01L 21/304; H01L 21/3065; H01L 21/311; H01L 27/146

(52) U.S. Cl. CPC H01L 21/56; H01L 21/02164; H01L 21/304; H01L 21/3065; H01L 21/31116; H01L 27/14698

(57) ABSTRACT

A method for protecting active layers of electronic chips including the following successive steps: using a stack comprising, successively: a carrier substrate, a hybrid bonding interface, electronic chips, each comprising successively an active layer, a dielectric layer, and an initial substrate, forming a first encapsulating layer about the electronic chips, removing a part of the initial substrate by grinding and preserving a remaining part, forming a second encapsulating layer about the electronic chips, performing a directional etch of a part of the second encapsulating layer to: superficially expose the remaining part of the initial substrate, and preserve the second encapsulating layer extending over the flanks of the electronic chips, and performing a selective chemical etch of the remaining part of the initial substrate.

### TECHNICAL FIELD

The invention relates to the technical field of protecting active layers of electronic chips.

The invention is notably applicable to protecting active layers made of III-V material(s) for image sensors.

### PRIOR ART

A die-to-wafer transfer method, known in the prior art, can be used to obtain a stack comprising successively:
a carrier substrate,
a hybrid bonding interface having a metal material and a dielectric material,
electronic chips assembled on the carrier substrate via the hybrid bonding interface, each comprising successively an active layer, a dielectric layer and an initial substrate.

The hybrid bonding interface enables the transfer of an electric signal. The method then conventionally involves removing the initial substrate, usually by grinding.

This removal of the initial substrate by grinding is not entirely satisfactory in so far as it is liable to:
(i) damage the active layer (in particular the flanks),
(ii) leave residue of the initial substrate.

In particular, leaving residue of the initial substrate may adversely affect the performance of the electronic chips used in image sensors. This is because the residue of the initial substrate causes spectral absorption issues.

### SUMMARY OF THE INVENTION

The invention aims to fully or partially address the aforementioned drawbacks. To this end, the invention relates to a method for protecting active layers of electronic chips, including the following successive steps:
a) using a stack comprising, successively:
   a carrier substrate,
   a hybrid bonding interface having a metal material and a dielectric material,
   electronic chips assembled on the carrier substrate via the hybrid bonding interface, each comprising successively an active layer, a dielectric layer and an initial substrate,
b) forming a first encapsulating layer about the electronic chips, the first encapsulating layer being made of a first dielectric material,
c) removing a part of the initial substrate from each of the electronic chips by grinding and preserving a remaining part of said initial substrate,
d) forming a second encapsulating layer about the electronic chips, the second encapsulating layer being made of a second dielectric material,
e) performing a directional etch of a part of the second encapsulating layer extending over the remaining part of the initial substrate of each of the electronic chips to:
   superficially expose the remaining part of the initial substrate of each of the electronic chips,
   preserve the second encapsulating layer extending over the flanks of the electronic chips,
f) performing a selective chemical etch of the remaining part of the initial substrate of each of the electronic chips, step f) being carried out with a chemical etchant that permits selective etching of the remaining part of the initial substrate with respect to the second encapsulating layer and with respect to the dielectric layer.

Thus, such a method according to the invention effectively protects the active layer when removing the initial substrate, while significantly reducing the quantity of residue of the initial substrate.

The protection of the active layer from the grinding carried out during step c) is provided initially by the first encapsulating layer formed during step b). The grinding carried out during step c) usually causes damage to the flanks of the first encapsulating layer. The second encapsulating layer formed during step d) enables the flanks of the electronic chips (and therefore the flanks of the active layer) to continue to be effectively protected during subsequent steps of the method according to the invention, in particular step f).

Step e) enables the remaining part of the initial substrate to be exposed in order to carry out a selective chemical etch. Step e) is a directional etch intended to preserve the second encapsulating layer to protect the flanks of the electronic chips (and therefore the flanks of the active layer) during step f).

Step f) enables the remaining part of the initial substrate to be efficiently removed (less residue than in the prior art) while keeping the active layer intact. This is because the upper part of the active layer is protected by the dielectric layer, which forms an etch stop layer. The lateral parts of the active layer are protected by the second encapsulating layer, which also forms an etch stop layer.

The method according to the invention may comprise one or more of the following features.

According to one feature of the invention, the method includes a step g) of planarizing the stack obtained on completion of step f), step g) preferably being carried out by chemical mechanical polishing or by grinding.

One advantage is therefore the removal of the parts projecting from the second encapsulating layer (in relation to the free surface of the remaining part of the initial substrate) appearing on completion of step e).

According to one feature of the invention, the first encapsulating layer formed during step b) has a thickness of between 500 nm and 2 μm.

One advantage is therefore a satisfactory compromise between effective protection and processing time.

According to one feature of the invention, the first and second dielectric materials of the first and second encapsulating layers formed respectively during steps b) and d) are chosen from a polyepoxide, silicon dioxide, a multilayer material comprising silicon nitride and silicon dioxide.

According to one feature of the invention, the first and second dielectric materials of the first and second encapsulating layers formed respectively during steps b) and d) are identical.

One advantage is therefore the simpler implementation of the method.

According to one feature of the invention, the second dielectric material of the second encapsulating layer formed during step d) is identical to the material of the dielectric layer of the electronic chips of the stack used during step a).

One advantage is therefore the increased options when choosing an etchant that permits selective etching of the remaining part of the initial substrate with respect to the second encapsulating layer and with respect to the dielectric layer. In other words, the etchant need only authorize a selective etch between a first material (initial substrate) and a second material (second encapsulating layer and dielectric layer).

According to one feature of the invention, the electronic chips of the stack used in step a) are chosen from image sensors and radio frequency chips. Other applications are of course possible.

According to one feature of the invention, the active layer includes a plurality of semiconductor sublayers, each semiconductor sublayer preferably being made of a III-V material.

According to one feature of the invention, the directional etch carried out during step e) is a dry plasma etch.

One advantage is therefore the simple implementation of the method.

According to one feature of the invention:
the initial substrate of the electronic chips of the stack used during step a) is made of silicon,
the dielectric layer of the electronic chips of the stack used during step a) is made of silicon dioxide,
the second dielectric material of the second encapsulating layer formed during step d) is silicon dioxide,
the chemical etchant used to carry out step f) is tetramethylammonium hydroxide.

### Definitions

“Active layer” means a layer performing the main function of the electronic chip, for example the photosensitivity function in the case of an image sensor.
“Layer” means a single layer or a plurality of sublayers of the same type.
“Electronic chip or die” means an electronic component including a substrate (referred to as the initial substrate) following application of technological steps intended to form said electronic component.
“Substrate” means a self-supporting physical carrier made of a base material from which a device for any application may be formed, notably an electronic, mechanical or optical device. A substrate may be a “wafer”, generally taking the form of a disc obtained by cutting an ingot of a crystalline material.
“Successively” means that the elements of the stack are arranged one on top of the other in a defined order from bottom to top under the normal conditions of use, i.e. along the normal to the surface of the carrier substrate receiving the electronic chips in general.
“Hybrid bonding interface” means a contact zone between the carrier substrate and the active layer that is designed to enable both direct metal/metal bonding and direct dielectric/dielectric bonding. The contact zone may include:
(i) a first interconnect structure formed on the free surface of the carrier substrate,
(ii) a second interconnect structure on which the electronic chips are formed.
   The hybrid bonding interface is then the contact surface between the first and second interconnect structures.
“Interconnect structure” means a stack of interconnect levels comprising metal tracks embedded in a dielectric material.
“Directional etch” means an anisotropic etch applied in a favoured direction, in this case along the normal to the surface of the carrier substrate receiving the electronic chips.
“Flanks” means the lateral parts of the electronic chips. Each electronic chip has opposing upper and lower parts connected together by the lateral parts.
“Selective etching” means that the part of the initial substrate to be etched (i.e. the remaining part of the initial substrate preserved during step c)) may be etched during step f) without attacking the second encapsulating layer and the dielectric layer. In practice, the etchant is usually selected such that the etch rate of the part of the initial substrate to be etched is at least 3 times greater (preferably at least 5 times greater, more preferably at least 10 times greater) than the etch rate of the second encapsulating layer and the dielectric layer.
“Chemical mechanical polishing” means a polishing method using:
(i) a polishing pad brought into contact with the free surface of the stack, the polishing pad and the free surface of the stack usually being movable in rotation about parallel axes of rotation (mechanical interaction),
(ii) a polishing solution, usually abrasive and corrosive, impregnating the polishing pad (chemical interaction).
“Thickness” means a dimension along the normal to the surface of the carrier substrate receiving the electronic chips.
“Identical materials” means that matter making up the materials is the same, although the thicknesses of the materials referred to as identical may be different.
“III-V material” means a binary alloy between elements in group Ill and group V respectively of the periodic table of elements.
The values X and Y, expressed using the expressions “between X and Y” are included in the defined range of values.

### BRIEF DESCRIPTION OF THE DRAWINGS

Other features and advantages will become apparent from the detailed description of various embodiments of the invention, the description being accompanied by examples and references to the appended drawings.

FIG. 1 is a schematic cross-sectional view illustrating step a) of a method according to the invention.

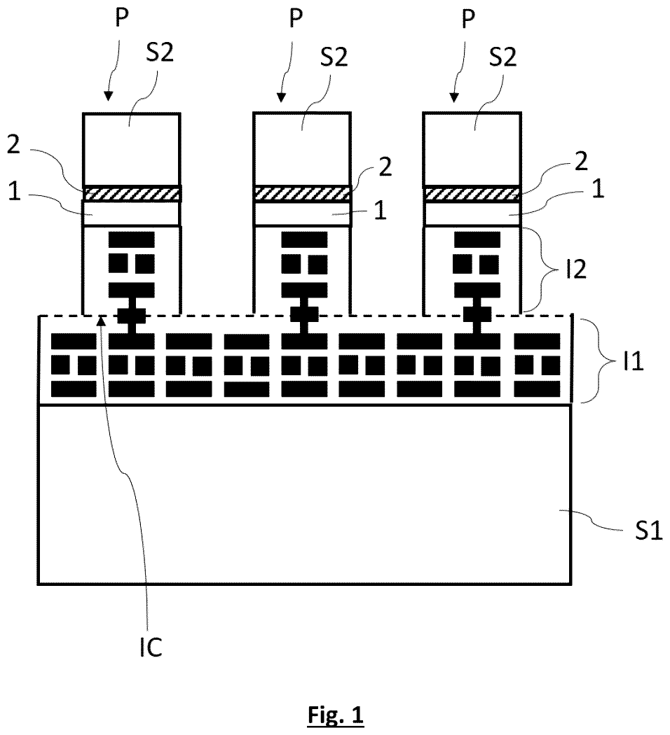

FIG. 2 is a schematic cross-sectional view illustrating step b) of a method according to the invention.

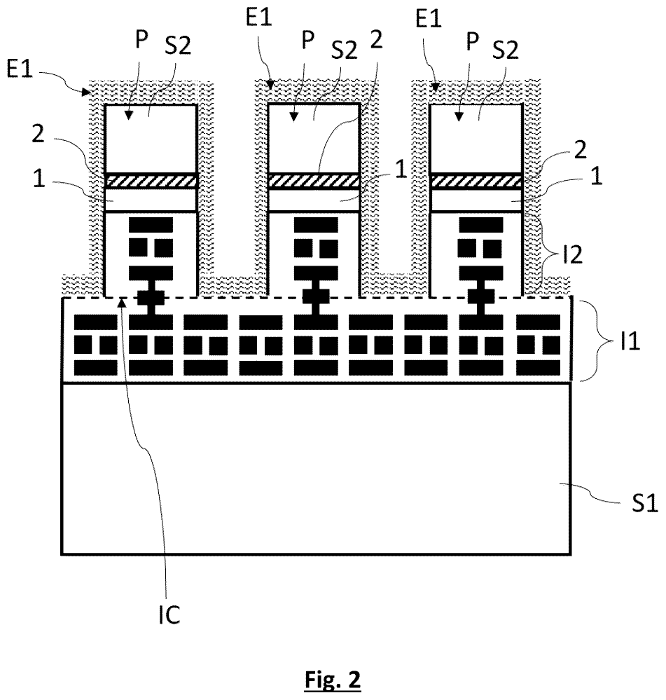

FIG. 3 is a schematic cross-sectional view illustrating step c) of a method according to the invention. This figure shows the case where the grinding carried out during step c) has entirely removed the lateral parts of the first encapsulating layer extending over the lateral parts of the electronic chips. In practice, the grinding carried out during step c) may leave behind a portion of the lateral parts of the first encapsulating layer extending over the lateral parts of the electronic chips.

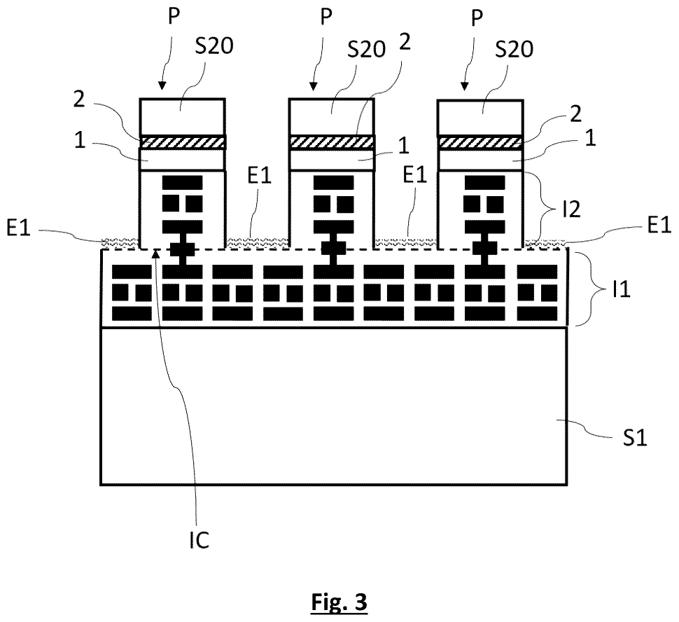

FIG. 4 is a schematic cross-sectional view illustrating step d) of a method according to the invention.

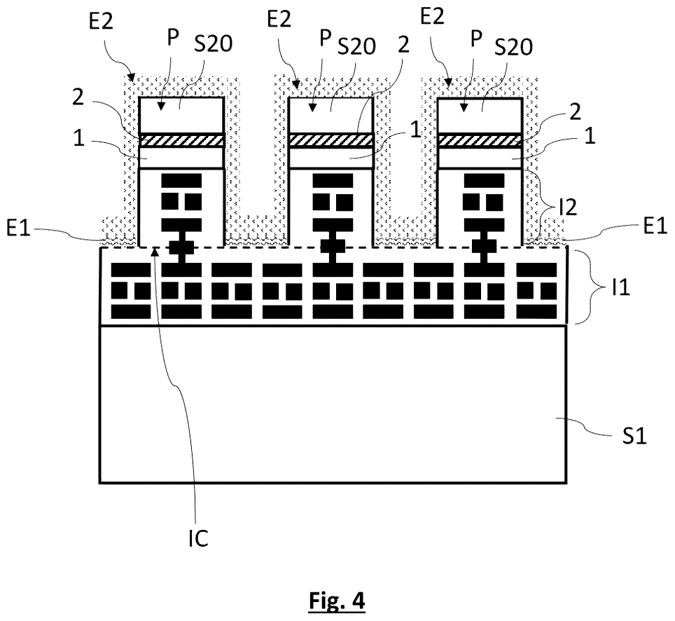

FIG. 5 is a schematic cross-sectional view illustrating step e) of a method according to the invention.

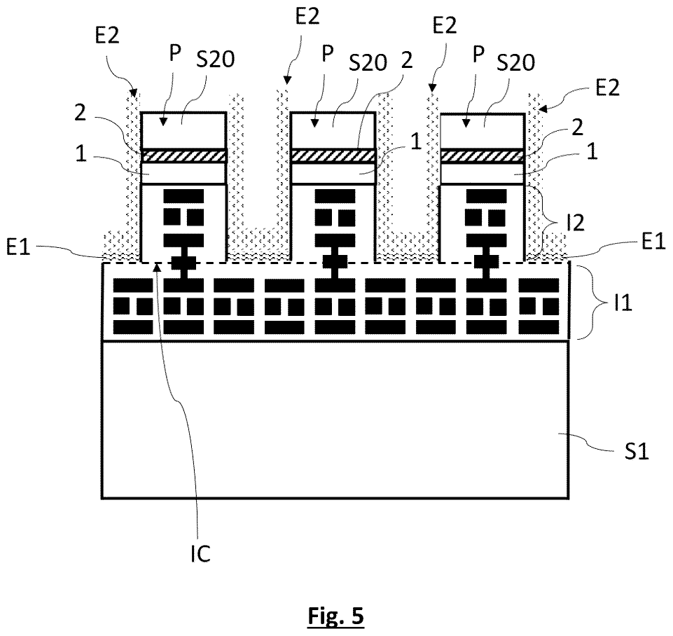

FIG. 6 is a schematic cross-sectional view illustrating step f) of a method according to the invention.

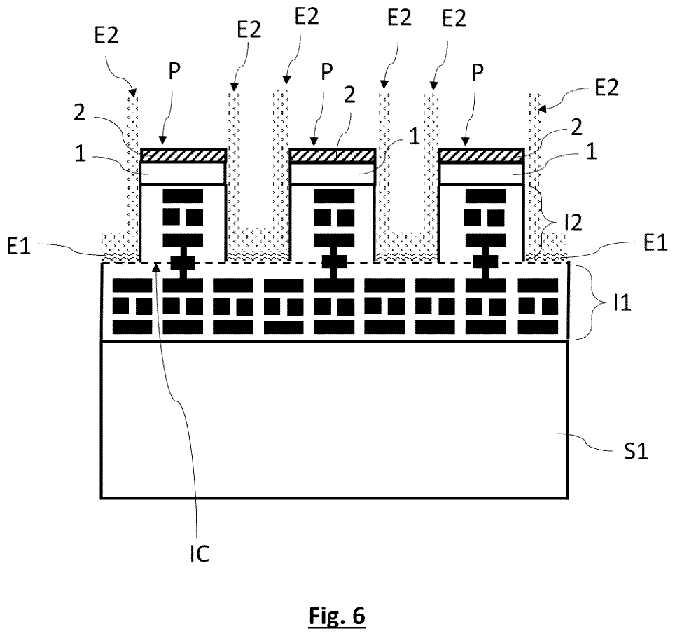

FIG. 7 is a schematic cross-sectional view illustrating step g) of a method according to the invention.

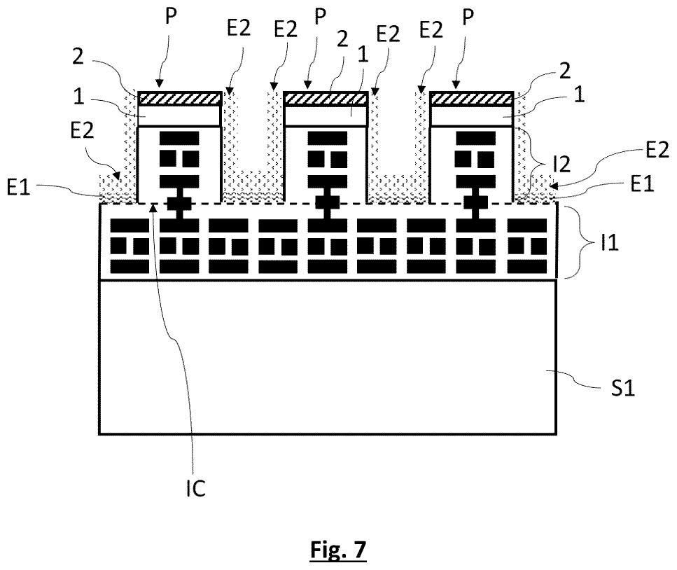

It should be noted that, for the sake of legibility and ease of understanding, the drawings described above are schematic and not necessarily to scale. In particular, the drawn interconnect structures are simplified and do not show the reality of the interconnections of the metal tracks. The cross sections are made normal to the surface of the carrier substrate receiving the electronic chips. The dashed line shows the hybrid bonding interface.

### DETAILED DESCRIPTION OF EMBODIMENTS

For the sake of simplicity, elements that are identical or that perform the same function in the various embodiments have been designated with the same references.

One subject of the invention is a method for protecting active layers 1 of electronic chips P including the following successive steps:
a) using a stack comprising, successively:
   a carrier substrate S1,
   a hybrid bonding interface IC having a metal material and a dielectric material,
   electronic chips P assembled on the carrier substrate S1 via the hybrid bonding interface IC, each comprising successively an active layer 1, a dielectric layer 2 and an initial substrate S2,
b) forming a first encapsulating layer E1 about the electronic chips P, the first encapsulating layer E1 being made of a first dielectric material,
c) removing a part of the initial substrate S2 from each of the electronic chips P by grinding and preserving a remaining part S20 of said initial substrate S2,
d) forming a second encapsulating layer E2 about the electronic chips P, the second encapsulating layer E2 being made of a second dielectric material,
e) performing a directional etch of a part of the second encapsulating layer E2 extending over the remaining part S20 of the initial substrate S2 of each of the electronic chips P to:
   superficially expose the remaining part S20 of the initial substrate S2 of each of the electronic chips P,
   preserve the second encapsulating layer E2 extending over the flanks of the electronic chips P,
f) performing a selective chemical etch of the remaining part S20 of the initial substrate S2 of each of the electronic chips P, step f) being carried out with a chemical etchant that permits selective etching of the remaining part S20 of the initial substrate S2 with respect to the second encapsulating layer E2 and with respect to the dielectric layer 2.

### Step a)

The stack used in step a) comprises successively:
a carrier substrate S1,
a hybrid bonding interface IC having a metal material and a dielectric material,
electronic chips P assembled on the carrier substrate S1 via the hybrid bonding interface IC, each comprising successively an active layer 1, a dielectric layer 2 and an initial substrate S2.

By way of non-limiting example, the carrier substrate S1 may be made of silicon.

The hybrid bonding interface IC is a contact zone between the carrier substrate S1 and the active layer 1 of each of the electronic chips P. The contact zone is designed to enable both direct metal/metal bonding and direct dielectric/dielectric bonding. The contact zone may include:
a first interconnect structure 11 formed on the free surface of the carrier substrate S1,
a second interconnect structure 12 on which the electronic chips P are formed.

The hybrid bonding interface IC is then the contact surface between the first and second interconnect structures 11, 12. By way of non-limiting example, the metal material of the hybrid bonding interface IC may be copper. By way of non-limiting example, the dielectric material of the hybrid bonding interface IC may be silicon dioxide.

By way of non-limiting example, the electronic chip P, provided with the second interconnect structure 12, may have a thickness in the order of 775 μm during step a).

The active layer 1, the dielectric layer 2 and the initial substrate S2 of each of the electronic chips P are advantageously obtained from an advanced semiconductor-on-insulator (SeOI) substrate that can notably be obtained using the Smart-Cut™ technique.

The electronic chips P may be image sensors, notably infrared image sensors. The active layer 1 advantageously includes a plurality of semiconductor sublayers, each semiconductor sublayer preferably being made of a III-V material. By way of non-limiting example, the active layer 1 of each of the electronic chips P may include successively a first sublayer of indium phosphide InP, a second sublayer of gallium arsenide GaAs, and a third sublayer of indium phosphide InP.

The electronic chips P may also be radio frequency (RF) chips. Other applications are of course possible.

### Step b)

The first encapsulating layer E1 is formed during step b) about the electronic chips P. The term “about” means that the first encapsulating layer E1 extends over the upper part and over the lateral parts of the electronic chips P. Step b) is carried out using a deposition technique enabling the first encapsulating layer E1 to follow the surface topography of the electronic chips P. It is not necessary for the deposition technique to produce conformal deposition (degree of conformity equal to 100%). In other words, the deposition technique is chosen so as to have a degree of conformity (ratio between the width of the flanks of the first deposited encapsulating layer E1 and the thickness at the surface of the first deposited encapsulating layer E1) that makes it possible to follow the surface topography of the electronic chips P. By way of non-limiting example, the first encapsulating layer E1 may be formed during step b) by chemical vapour deposition.

The first encapsulating layer E1 is made of a first dielectric material. The first dielectric material is advantageously chosen from a polyepoxide, silicon dioxide, a multilayer material comprising silicon nitride and silicon dioxide.

The first encapsulating layer E1 formed during step b) advantageously has a thickness of between 500 nm and 2 μm.

### Step c)

The grinding is carried out during step c) to remove a part of the initial substrate S2 from each of the electronic chips P and to preserve a remaining part S20 of said initial substrate S2.

By way of non-limiting example, the electronic chip P, provided with the second interconnect structure 12, may have a thickness in the order of 10 μm on completion of step c).

### Step d)

The second encapsulating layer E2 is formed during step b) about the electronic chips P. The term “about” means that the second encapsulating layer E2 extends over the upper part and over the lateral parts of the electronic chips P. If the grinding carried out in step c) does not entirely remove the lateral parts of the first encapsulating layer E1 (extending over the lateral parts of the electronic chips P), the second encapsulating layer E2 extends over the upper part of the electronic chips P and over the lateral parts of the first encapsulating layer E1. Step d) is carried out using a deposition technique enabling the second encapsulating layer E2 to follow the surface topography of the electronic chips P. It is not necessary for the deposition technique to produce conformal deposition (degree of conformity equal to 100%). In other words, the deposition technique is chosen so as to have a degree of conformity (ratio between the width of the flanks of the second deposited encapsulating layer E2 and the thickness at the surface of the second deposited encapsulating layer E2) that makes it possible to follow the surface topography of the electronic chips P. By way of non-limiting example, the second encapsulating layer E2 may be formed during step d) by chemical vapour deposition.

The second encapsulating layer E2 is made of a second dielectric material. The second dielectric material is advantageously chosen from a polyepoxide, silicon dioxide, a multilayer material comprising silicon nitride and silicon dioxide. The second dielectric material is advantageously identical to the first dielectric material. The second dielectric material is advantageously identical to the material of the dielectric layer 2 of the electronic chips P of the stack used during step a).

The second encapsulating layer E2 formed during step d) advantageously has a thickness of between 500 nm and 2 μm.

### Step e)

The etching carried out during step e) is a directional etch of a part of the second encapsulating layer E2, said part extending over the remaining part S20 of the initial substrate S2 of each of the electronic chips P.

The directional etch is carried out during step e) to:
superficially expose the remaining part S20 of the initial substrate S2 of each of the electronic chips P,
preserve the second encapsulating layer E2 extending over the flanks of the electronic chips P.

The directional etch carried out during step e) is advantageously a dry plasma etch.

### Step f)

The etching carried out during step f) is a selective chemical etch of the remaining part S20 of the initial substrate S2 of each of the electronic chips P.

Step f) is carried out with a chemical etchant that permits selective etching of the remaining part S20 of the initial substrate S2 with respect to the second encapsulating layer E2 and with respect to the dielectric layer 2.

By way of non-limiting example, the electronic chip P, provided with the second interconnect structure 12, may have a thickness of between 4 μm and 5 μm on completion of step f).

### Step g)

The method advantageously includes a step g) of planarizing the stack obtained on completion of step f). Step g) is preferably carried out by chemical mechanical polishing or grinding.

### Step h)

The method advantageously includes a step h) of forming electric contact pads that are electrically connected to the hybrid bonding interface IC. The electric contact pads may be formed on the second interconnect structure 12. By way of non-limiting example, the electric contact pads may be made of aluminium or a Cu/Ni/Au alloy.

### EXAMPLE IMPLEMENTATION

The initial substrate S2 of the electronic chips P of the stack used during step a) is made of silicon. The dielectric layer 2 of the electronic chips P of the stack used during step a) is made of silicon dioxide. The second dielectric material of the second encapsulating layer E2 formed during step d) is silicon dioxide. The chemical etchant used to carry out step f) is tetramethylammonium hydroxide.

The invention is not limited to the disclosed embodiments. Those skilled in the art will be capable of considering technically workable combinations thereof and of substituting equivalents therefor.

1. A method for protecting active layers of electronic chips, including the following successive steps:
(a) using a stack comprising, successively:
a carrier substrate,
a hybrid bonding interface having a metal material and a dielectric material, and
electronic chips assembled on the carrier substrate via the hybrid bonding interface, each comprising successively an active layer, a dielectric layer, and an initial substrate,
(b) forming a first encapsulating layer about the electronic chips, the first encapsulating layer being made of a first dielectric material,
(c) removing a part of the initial substrate from each of the electronic chips by grinding and preserving a remaining part of said initial substrate,
(d) forming a second encapsulating layer about the electronic chips, the second encapsulating layer being made of a second dielectric material,
(e) performing a directional etch of a part of the second encapsulating layer extending over the remaining part of the initial substrate of each of the electronic chips to:
superficially expose the remaining part of the initial substrate of each of the electronic chips, and
preserve the second encapsulating layer extending over the flanks of the electronic chips, and
(f) performing a selective chemical etch of the remaining part of the initial substrate of each of the electronic chips, the step (f) being carried out with a chemical etchant that permits selective etching of the remaining part of the initial substrate with respect to the second encapsulating layer and with respect to the dielectric layer.

2. The method according to claim 1, further including a step (g) of planarizing the stack obtained on completion of the step (f), the step (g) being performed by chemical mechanical polishing or by grinding.

3. The method according to claim 1, wherein the first encapsulating layer formed during the step (b) has a thickness of between 500 nm and 2 μm.

4. The method according to claim 1, wherein the first and second dielectric materials of the first and second encapsulating layers formed respectively during the steps (b) and (d) are chosen from a polyepoxide, silicon dioxide, a multilayer material comprising silicon nitride and silicon dioxide.

5. The method according to claim 1, wherein the first and second dielectric materials of the first and second encapsulating layers formed respectively during the steps (b) and (d) are identical.

6. The method according to claim 1, wherein the second dielectric material of the second encapsulating layer formed during the step (d) is identical to the material of the dielectric layer of the electronic chips of the stack used during the step (a).

7. The method according to claim 1, wherein the electronic chips of the stack used in the step (a) are chosen from image sensors and radio frequency chips.

8. The method according to claim 1, wherein the active layer includes a plurality of semiconductor sublayers, each semiconductor sublayer preferably being made of a III-V material.

9. The method according to claim 1, wherein the directional etch carried out during the step (e) is a dry plasma etch.

10. The method according to claim 1, wherein:
the initial substrate of the electronic chips of the stack used during the step (a) is made of silicon,
the dielectric layer of the electronic chips of the stack used during the step (a) is made of silicon dioxide,
the second dielectric material of the second encapsulating layer formed during the step (d) is silicon dioxide, and
the chemical etchant used to perform the step (f) is tetramethylammonium hydroxide.
